(19) United States
(12) Patent Application Publication
(10) Pub. No.: US 2006/0102895 A1
(43) Pub. Date: May 18, 2006

(54) Precursor compositions for forming tantalum-containing films, and tantalum-containing barrier films and copper-metallized semiconductor device structures

(76) Inventors: Bryan C. Hendrix, Danbury, CT (US); Jeffrey F. Roeder, Brookfield, CT (US); Thomas H. Baum, New Fairfield, CT (US); Tianniu Chen, Rocky Hill, CT (US); Chongying Xu, New Milford, CT (US); Gregory T. Stauf, New Milford, CT (US)

Correspondence Address: INTELLECTUAL PROPERTY / TECHNOLOGY LAW, PO BOX 14329, RESEARCH TRIANGLE PARK, NC, 27709, US

(21) Appl. No.: 11/273,959

(22) Filed: Nov. 15, 2005

Related U.S. Application Data
(60) Provisional application No. 60/628,422, filed on Nov. 16, 2004.
(60) Provisional application No. 60/636,284, filed on Dec. 15, 2004.

(51) Int. Cl. H01L 29/08; C07F 9/00; C07F 17/00; H01L 21/469

(52) U.S. Cl. 257/40; 556/42; 556/43; 438/765; 977/827

(57) ABSTRACT

Tantalum compositions of Formulae I-V hereof are disclosed, having utility as precursors for forming tantalum-containing films. The tantalum compositions are amenable to usage involving chemical vapor deposition and atomic layer deposition processes, to form semiconductor device structures, including a dielectric layer, a barrier layer overlying the dielectric layer, and copper metallization overlying the barrier layer, wherein the barrier layer includes a Ta-containing layer including sufficient carbon so that the Ta-containing layer is amorphous. In one preferred implementation, the semiconductor device structure is fabricated by depositing the Ta-containing barrier layer, via CVD or ALD, from a precursor including a Ta alkylidene compound, at a temperature below 400° C., in a reducing or inert atmosphere.

### CROSS-REFERENCE TO RELATED APPLICATIONS

The benefit of U.S. Provisional Patent Application No. 60/628,422 filed Nov. 16, 2004 and of U.S. Provisional Patent Application No. 60/636,284 filed Dec. 15, 2004 is hereby claimed under the provisions of 35 USC 119. The disclosures of said provisional applications are hereby incorporated by reference herein, for all purposes.

### FIELD OF THE INVENTION

The present invention relates to precursor compositions that are useful for forming tantalum-containing films, e.g., by chemical vapor deposition (CVD) or atomic layer deposition (ALD), as well as to tantalum-containing barrier films and to copper-metallized semiconductor device structures including tantalum-containing films.

### DESCRIPTION OF THE RELATED ART

In the field of semiconductor manufacturing, copper (Cu) and low k dielectrics are being increasingly employed in high performance silicon integrated circuits. Since Cu is very mobile in silicon (Si) and silicon dioxide (SiO₂), effective diffusion barriers against Cu migration are required for the use of Cu metallization, inasmuch as the copper/interlayer dielectric interface determines the stability and reliability of the metallization scheme.

A variety of refractory metals, refractory metal nitrides, and metal-silicon-nitrogen compounds have been intensively investigated for use as barrier material. Among such materials, tantalum (Ta) and tantalum nitrides (TaN) are considered to be among the most promising candidates because of their stability under high temperature, high degree of adhesion, low resistivity, uniformity of their films and their inertness towards Cu. As the size of the pattern shrinks and the aspect ratio increases, vapor deposition techniques, e.g., chemical vapor deposition (CVD), atomic layer deposition (ALD), digital CVD, pulsed CVD, or the like, are necessary to deposit the barrier layer, in order to minimize barrier layer thickness while achieving effective barrier properties.

Against this background of continuous shrinkage in feature size and progressive increase in aspect ratio, chemical vapor deposition (CVD) and atomic layer deposition (ALD) are increasingly preferred for depositing thin, conformal and smooth barrier layers in vias and trenches. For such applications, suitable tantalum precursors are required for forming tantalum-containing barrier material on substrates.

From a practical standpoint, only PDMAT [Ta(NMe₂)₅], PEMAT [Ta(NEtMe)₅] and TBTDET [t-BuN═Ta(NEt₂)₃] are viable for use as TaN CVD precursors. Thermal stability is always problematic for such precursors. For example, PDMAT is a solid with a melting point of 167° C., and decomposes at temperatures above 80° C. PEMAT is a low melting point solid, and also decomposes at above 80° C.

In sum, there is a continuing need in the art for tantalum precursors useful for deposition applications, e.g., to form copper barrier structures.

In current practice, copper barrier structures are formed by reactive sputter deposition of a TaN layer onto a patterned, nominally dense dielectric, followed by sputter deposition of Ta metal prior to sputter deposition of the copper seed layer.

Current CVD and ALD approaches include use of Ta amido or Ta imido compounds as precursors to form a TaN barrier layer that exhibits good adhesion to the underlying dielectric film. This practice has a significant drawback in that it involves the presence of active nitrogen species deriving from the precursor and/or reactive gas environment in the deposition chamber, to form the barrier layer. Since low k dielectric materials have intrinsic porosity, there is potential for photoresist poisoning by nitrogen that has been absorbed by the dielectric during the deposition of the TaN barrier layer.

There is correspondingly a need for barrier layers, e.g., for copper metallization of semiconductor device structures, that do not introduce nitrogen to the underlying dielectric film.

### SUMMARY OF THE INVENTION

The present invention relates generally to precursor compositions for forming tantalum-containing films, as well as to tantalum-containing films, such as may be employed as barrier layers in semiconductor devices utilizing copper metallization, as well as to semiconductor device structures including tantalum-containing films.

In one aspect, the present invention relates to a tantalum composition, selected from the group consisting of compositions of Formulae I-V below: 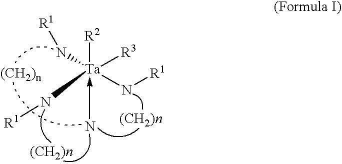
wherein: R₁, R₂, and R₃ can be the same as or different from one another, and each is independently selected from hydrocarbyl, hydrogen, halogen, silyl, hydrazide and amino; and n is an integer having a value of from 1 to 4 inclusive; 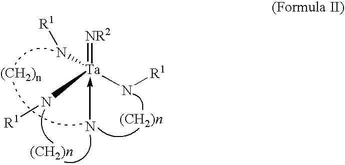
wherein: R₁ and R₂ can be the same as or different from one another, and each is independently selected from hydrocarbyl, hydrogen, halogen, silyl, hydrazide and amino; and n is an integer having a value of from 1 to 4 inclusive; 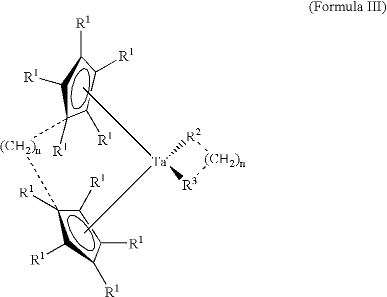
wherein: R¹, R² and R³ can be the same as or different from one another, and each is independently selected from hydrogen and hydrocarbyl(ene) substituents; and n is selected from the values of 0, 1, 2, 3 and 4, with the proviso that when n is not zero, R² and R³ can be the same as or different from one another, and each is independently selected from bidentate hydrocarbyl ligands; 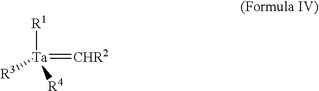
wherein: R¹, R², R³ and R⁴ can be the same as or different from one another, and each is independently selected from hydrogen and hydrocarbyl, halogen, silyl, hydrazide and amino; and 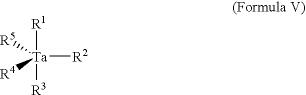
wherein: R¹, R², R³ and R⁴ and R⁵ can be the same as or different from one another, and each is independently selected from hydrogen and hydrocarbyl, halogen, silyl, hydrazide and amino.

The invention in another aspect relates to a tantalum precursor formulation, including a tantalum composition as described in the preceding paragraph [0012], in a solvent medium

In a further aspect, the invention relates to a method of synthesizing a tantalum composition as described in paragraph [0012] hereof, in which the method includes conducting synthesis according to a procedure selected from the group of synthesis procedures consisting of Scheme A, Scheme B and Scheme C, as hereinafter described.

A still further aspect of the invention relates to a method of forming a tantalum-containing material on a substrate, including volatilizing a tantalum composition as described in paragraph [0012] hereof, to form a precursor vapor, and depositing tantalum on the substrate from the precursor vapor under deposition conditions therefor.

In another aspect, the present invention relates to a semiconductor device structure, including a dielectric layer, a barrier layer overlying the dielectric layer, and copper metallization overlying the barrier layer, wherein the barrier layer includes a Ta-containing layer including sufficient carbon so that the Ta-containing layer is amorphous.

A still further aspect of the invention relates to a method of forming a Ta-containing barrier layer on a substrate including a dielectric layer thereon, including depositing the Ta-containing barrier layer by a process including CVD or ALD, from a precursor including a Ta alkylidene compound, at a temperature below 400° C., in a reducing atmosphere.

Yet another aspect of the invention relates to a method of inhibiting copper migration in a structure including copper and material adversely affected by copper migration, comprising providing a Ta-containing barrier layer between said copper and said material, including depositing the Ta-containing barrier layer by a process including CVD or ALD, from a precursor including a Ta alkylidene compound, at a temperature below 400° C., in a reducing or inert atmosphere.

Additional aspects of the invention relate to making a semiconductor device, comprising forming a migration barrier by a vapor deposition process using a vapor deposition precursor including a tantalum composition as described in the preceding paragraph [0012], and semiconductor manufacturing methods including use of a tantalum composition of such type.

Other aspects, features and advantages of the invention will be more fully apparent from the ensuing disclosure and appended claims.

### BRIEF DESCRIPTION OF THE DRAWINGS

FIG. 1 is a 1H NMR plot of NpLi, Np₂Zn, Np₃TaCl₂, Np₃Ta(═CHBu^{t}), where Np=neopentyl.

FIG. 2 is an STA diagram of Np₃Ta(═CHBu^{t}) (8.62 mg sample with 26.8% mass residual).

FIG. 3 is a graph of deposition rate, in Angstroms per minute, as a function of temperature (range of 300° C. to 550° C., as well as inverse temperature, 1/T, where T is the temperature in degrees Kelvin), using as the precursor tantalum neopentylidene ((Bu^{t}CH₂)₃Ta(═CHBu^{t})), wherein Bu^{t}=tert-butyl, in a hydrogen atmosphere in the deposition chamber, at pressure of 400 millitorr (“400 mTorr ATMI”) and 800 millitorr (“800 mTorr ATMI”), against the comparison case of Ta carbide films formed at higher temperature of 556° C. and at 506° C. (“800 mTorr Nat. Chiao Tung”).

FIG. 4 is a graph of deposition rate, in Angstroms per minute, as a function of pressure, in millitorr, at deposition temperature of 300° C., 350° C., 500° C. and 520° C., using as the precursor tantalum neopentylidene ((Bu^{t}CH₂)₃Ta(═CHBu^{t})), wherein Bu^{t}=tert-butyl, in a hydrogen atmosphere in the deposition chamber.

FIG. 5 is an X-ray diffraction spectrum of specific films using Cu Kₐₗₚₕₐ radiation monochromated with a crystal monochrometer.

FIG. 6 is a schematic illustration of a semiconductor device structure according to one embodiment of the present invention, featuring an amorphous Ta-containing barrier film and copper metallization.

### DETAILED DESCRIPTION OF THE INVENTION AND PREFERRED FEATURES THEREOF

The present invention relates in various aspects to precursor compositions useful for forming tantalum-containing films, as well as to tantalum-containing films, such as may be employed as barrier layers in semiconductor devices utilizing copper metallization, as well as to semiconductor device structures including tantalum-containing films.

As used herein, the term “semiconductor device structures” is intended to be broadly construed to include microelectronic devices, products, components, assemblies and subassemblies that include a semiconductor material as a functional material therein. Illustrative examples of semiconductor device structures include, without limitation, resist-coated semiconductor substrates, flat-panel displays, thin-film recording heads, microelectromechanical systems (MEMS), and other advanced microelectronic components. The semiconductor device structure may include patterned and/or blanketed silicon wafers, flat-panel display substrates or fluoropolymer substrates. Further, the semiconductor device structure may include mesoporous or microporous inorganic solids.

The present invention in one aspect relates to a class of precursors selected from among precursors of Formula I below and precursors of Formula II below, wherein: R₁, R₂, and R₃ can be the same as or different from one another, and each is independently selected from hydrocarbyl (e.g., C₁-C₈ alkyl), hydrogen, halogen (chlorine, fluorine, bromine, iodine), silyl, hydrazide (for example Me₂NNH—) and amino (for example Me₂N—, MeHN—, etc.); and n is an integer having a value of from 1 to 4.

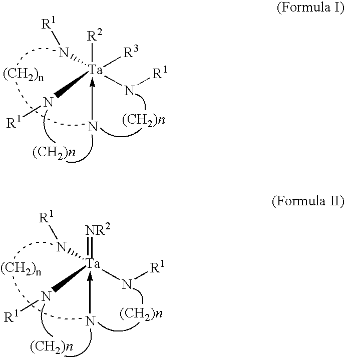

The precursors of Formula I and Formula II can be made by the synthesis reactions set out in Scheme A below.

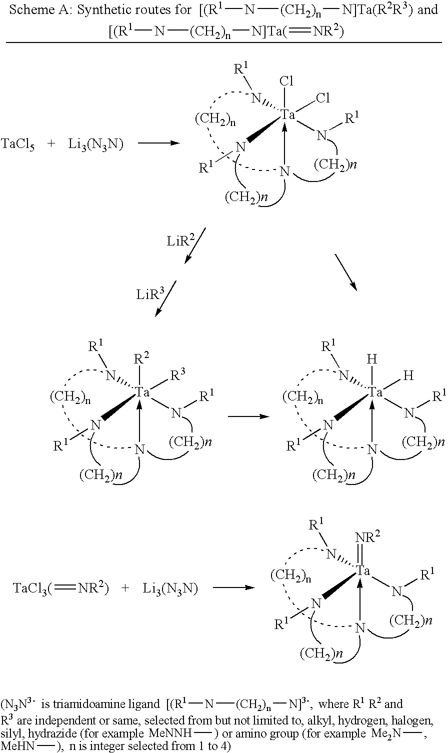

In the above synthesis reactions, the co-reactant used with the polychlorotantalum starting material (tantalum pentachloride in the first reaction for producing the precursor of Formula I, and trichloroimidotantalum in the second reaction for producing the precursor of Formula II) is trilithiumtriamidoamine (Li₃(N₃N)), containing the triamidoamine ligand (N₃N³⁻).

The precursors of Formula I and Formula II are useful for forming tantalum-containing films, e.g., involving CVD and ALD of tantalum nitride and Ta metal films. These precursors also have utility as low temperature deposition precursors for forming Ta₂O₅ and other Ta oxide films, e.g., in the fabrication of back-end capacitors.

These novel complexes are yielded as monomers that are relatively rigid in solution due to the bulky triamidoamine ligands utilized in their synthesis. As a result, these complexes are readily purified, and their solution behavior in solvent media employed for liquid delivery processes, e.g., for CVD or ALD of Ta, TaN or Ta₂O₅ films is superior to that of PDMAT [Ta(NMe₂)₅], PEMAT [Ta(NEtMe)₅], etc.

The precursors of Formula I and Formula II are usefully employed for deposition of Ta-containing material on substrates, including, without limitation, deposition of Ta, TaN, Ta₂O₅, TaNSi, BiTaO₄, etc. The Ta-containing material may be deposited on the substrate in any suitable manner, with deposition processes such as CVD and ALD being preferred. Depending on the substituents employed, the Formula I and Formula II precursors may also be deposited by solid delivery techniques, e.g., in which the precursor is volatilized from a solid form under suitable temperature and pressure, e.g., vacuum, conditions.

The CVD process may be carried out in any suitable manner, with the volatilized precursor being conveyed to a CVD reactor for contact with a heated substrate, e.g., a silicon wafer-based structure, or other microelectronic device substrate. In such process, the volatilized precursor may be flowed to the CVD reactor in neat form, or, more typically, in a carrier gas stream, which may include inert gas, oxidant, reductant, co-deposition species, or the like.

The CVD process may be carried out by liquid delivery processing, in which the Ta precursor is dissolved or suspended in a solvent medium, which may include a single solvent or multi-solvent composition, as appropriate to the specific deposition application involved. Suitable solvents for such purpose include any compatible solvents that are consistent with liquid delivery processing, as for example, hydrocarbon solvents, ethers, etc., with a suitable solvent for a specific deposition application being readily determinable within the skill of the art based on the disclosure herein. In general, solvent species containing active hydrogen are desirably avoided for liquid delivery deposition processes.

The precursors of Formula I and Formula II have particular utility as CVD or ALD precursors for deposition of thin films of TaN and TaNSi as barriers in integrated circuits, e.g., integrated circuitry including dielectric material and copper metallization.

The precursors of Formula I and Formula II also have particular utility as CVD or ALD precursors for low temperature deposition of thin films of high k capacitor materials such as Ta₂O₅ and BiTaO₄.

The precursors of Formula I and Formula II, especially the hydrides of such formulae, also have particular utility as CVD or ALD precursors for deposition of Ta metal films as barriers in integrated circuits.

The present invention in another aspect includes a class of precursors selected from among precursors of Formula III below, wherein: R¹, R² and R³ can be the same as or different from one another, and each is independently selected from hydrogen and hydrocarbyl substituents (e.g., C₁-C₈ alkyl(ene), C₂-C₆ alkenyl(ene), etc.); and n is selected from the values of 0, 1, 2, 3 and 4, with the proviso that when n is not zero, R² and R³ can be the same as or different from one another, and each is independently selected from bidentate hydrocarbyl ligands, such as alkylene (e.g., C₁-C₈ alkylene), alkenylene (e.g., C₂-C₆ alkenylene), etc.

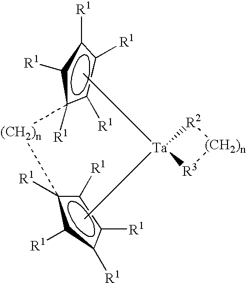

The precursors of Formula II have utility for CVD and ALD of Ta carbide and Ta metal films, as well as for low temperature deposition of TaN, Ta₂O₅ and other Ta-related oxide films for use in back-end capacitor fabrication.

The precursors of Formula III are readily synthesized starting from TaCl₅ in a two-step reaction sequence, corresponding to that shown in Scheme B below as illustratively set forth for forming (i-PrCp)₂TaR²R³, wherein i-Pr is isopropyl, and Cp is cyclopentadienyl.

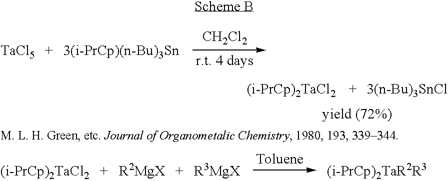

The Formula III precursors are monomeric and solution-stable due to the presence of the cyclopentadienyl structure. The R² and R³ ligands may be appropriately selected for the specific deposition application employed, e.g., for CVD or ALD deposition processing to form the desired Ta-containing material on the deposition substrate, within the skill of the art based on the disclosure herein. As a result of their monomeric character and solution-stable character, the Formula III precursors are readily purified, and their solution behavior in solvent media employed for liquid delivery processes, e.g., for CVD or ALD of Ta, TaN or Ta₂O₅ films is superior to that of Cp*TaH, Cp₂TaH₃, etc.

The precursors of Formula III are usefully employed for deposition of Ta-containing material on substrates, including, without limitation, deposition of Ta, TaN, Ta₂O₅, TaNSi, BiTaO₄, etc. The Ta-containing material may be deposited on the substrate in any suitable manner, with deposition processes such as CVD and ALD being preferred. Depending on the substituents employed, the Formula III precursors may also be deposited by solid delivery techniques, e.g., in which the precursor is volatilized from a solid form under suitable temperature and pressure, e.g., vacuum, conditions.

The CVD process may be carried out in any suitable manner, with the volatilized precursor being conveyed to a CVD reactor for contact with a heated substrate, e.g., a silicon wafer-based structure, or other microelectronic device substrate. In such process, the volatilized precursor may be flowed to the CVD reactor in neat form, or, more typically, in a carrier gas stream, which may include inert gas, oxidant, reductant, co-deposition species, or the like.

The CVD process may be carried out by liquid delivery processing, in which the Ta precursor is dissolved or suspended in a solvent medium, which may include a single solvent or multi-solvent composition, as appropriate to the specific deposition application involved. Suitable solvents for such purpose include any compatible solvents that are consistent with liquid delivery processing, as for example, hydrocarbon solvents, ethers, etc., with a suitable solvent for a specific deposition application being readily determinable within the skill of the art based on the disclosure herein. In general, solvent species containing active hydrogen are desirably avoided for liquid delivery deposition processes.

The precursors of Formula III have particular utility as CVD or ALD precursors for deposition of thin films of TaN and TaNSi as barriers in integrated circuits, e.g., integrated circuitry including dielectric material and copper metallization.

The precursors of Formula III also have particular utility as CVD or ALD precursors for low temperature deposition of thin films of high k capacitor materials such as Ta₂O₅ and BiTaO₄.

The present invention in another aspect includes a class of precursors selected from among precursors of Formula IV and Formula V below, wherein: R¹, R², R³, R⁴ and R⁵ can be the same as or different from one another, and each is independently selected from hydrogen and hydrocarbyl (e.g., C₁-C₈ alkyl, C₂-C₆ alkenyl, etc.), halogen (chlorine, fluorine, bromine, iodine), silyl, hydrazide (for example Me₂NNH—) and amino (for example Me₂N—, MeHN—, etc.).

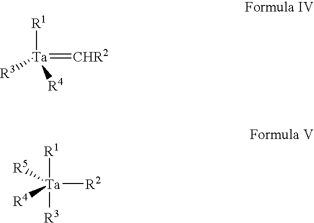

The Ta precursors of Formulae IV are readily synthesized by a synthesis route corresponding to that shown in Scheme C below for the synthesis of tantalum neopentylidene ((Bu^{t}CH₂)₃Ta(═CHBu^{t})), wherein Bu^{t}=tert-butyl, involving formation of neopentyl lithium (Bu^{t}CH₂Li), bisneopentyl zinc ((Bu^{t}CH₂)2Zn), and trisneopentyl tantalum dichloride ((Bu^{t}CH₂)₃TaCl₂) in the respective first three steps of the four-step process.

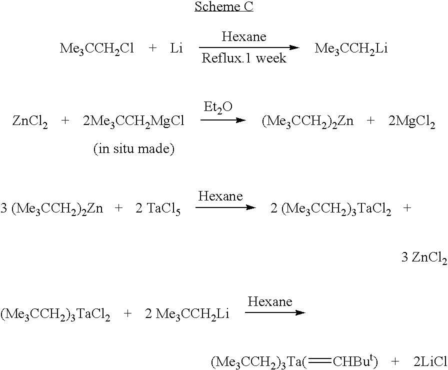

The product of Formula IV, once formed by a reaction sequence of the type shown in Scheme C, can be subjected to addition reaction to form the desired Formula V precursor composition, e.g., by alkylation, halogenation, hydrogenation, silylation, hydrazidation, or amination reaction.

The precursors of Formula IV and Formula V have utility for CVD and ALD of Ta nitride and Ta metal films, as well as for low temperature deposition of Ta₂O₅ and other Ta-related oxide films for use in back-end capacitor fabrication.

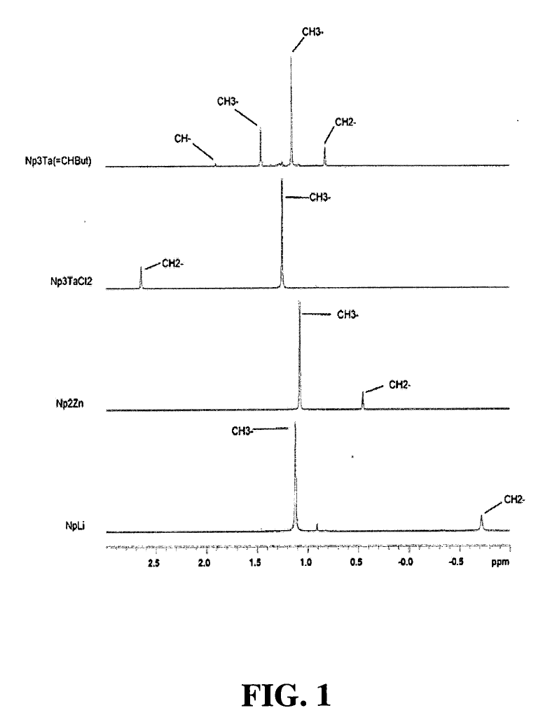

The synthesis procedure of Scheme C was carried out to produce tantalum neopentylidene. FIG. 1 shows a 1H NMR plot (Np=neopentyl) of NpLi, Np₂Zn, Np₃TaCl₂, Np₃Ta(═CHBu^{t}), as obtained in the successive reaction steps of such Scheme C.

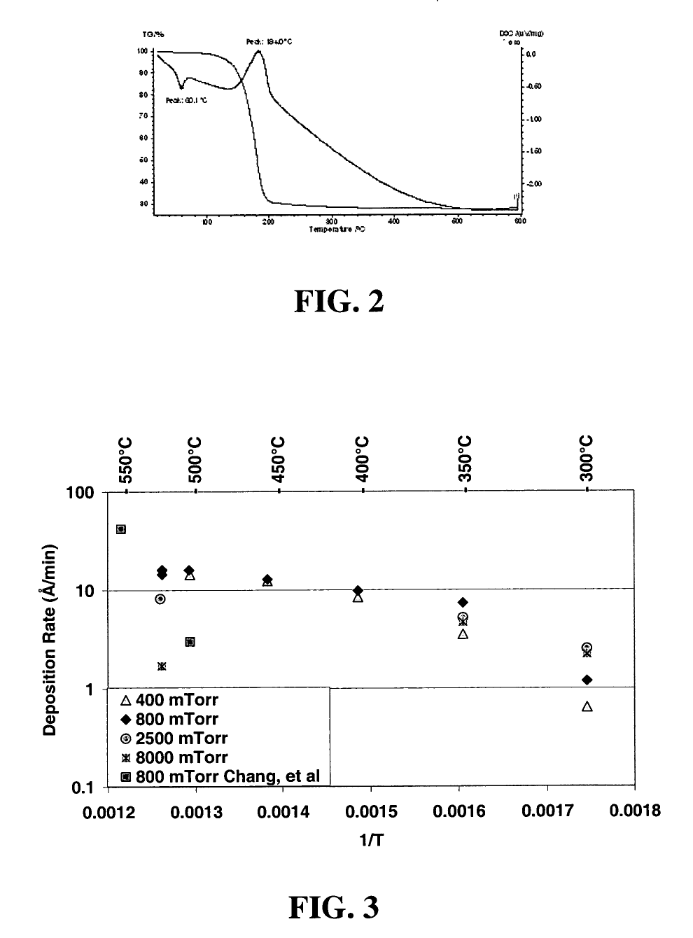

FIG. 2 is an STA diagram of Np₃Ta(═CHBu^{t}) (8.62 mg sample with 26.8% mass residual). The STA data of ((Bu^{t}CH₂)₃Ta(═CHBu^{t})) showed that it is not very stable above 180° C. under inert atmosphere and that it was not very volatile based on its relatively high mass residue of 26.8%. Accordingly, the data of FIG. 2 indicate that Ta neopentylidene is a suitable precursor for low temperature deposition applications for formation of Ta-containing films on substrates.

The precursors of Formula IV and Formula V are usefully employed for deposition of Ta-containing material on substrates, including, without limitation, deposition of Ta, TaN, Ta₂O₅, TaNSi, BiTaO₄, etc. The Ta-containing material may be deposited on the substrate in any suitable manner, with deposition processes such as CVD and ALD being preferred. Depending on the substituents employed, the Formula IV and Formula V precursors may also be deposited by solid delivery techniques, e.g., in which the precursor is volatilized from a solid form under suitable temperature and pressure, e.g., vacuum, conditions.

The CVD process may be carried out in any suitable manner, with the volatilized precursor being conveyed to a CVD reactor for contact with a heated substrate, e.g., a silicon wafer-based structure, or other microelectronic device substrate. In such process, the volatilized precursor may be flowed to the CVD reactor in neat form, or, more typically, in a carrier gas stream, which may include inert gas, oxidant, reductant, co-deposition species, or the like. Although the choice of specific process conditions for CVD is readily made by the skilled artisan based on the disclosure herein, it may be suitable in some applications to conduct chemical vapor deposition at process conditions including a deposition temperature in a range of from about 600 to about 900° K and deposition pressure in a range of from about 0 to about 100 Pascal.

The CVD process may be carried out by liquid delivery processing, in which the Ta precursor is dissolved or suspended in a solvent medium, which may include a single solvent or multi-solvent composition, as appropriate to the specific deposition application involved. Suitable solvents for such purpose include any compatible solvents that are consistent with liquid delivery processing, as for example, hydrocarbon solvents, ethers, etc., with a suitable solvent for a specific deposition application being readily determinable within the skill of the art based on the disclosure herein. In general, solvent species containing active hydrogen are desirably avoided for liquid delivery deposition processes.

The precursors of Formula IV and Formula V have particular utility as CVD or ALD precursors for deposition of thin films of TaN and TaNSi as barriers in integrated circuits, e.g., integrated circuitry including dielectric material and copper metallization.

The precursors of Formula IV and Formula V also have particular utility as CVD or ALD precursors for low temperature deposition of thin films of high k capacitor materials such as Ta₂O₅ and BiTaO₄.

The precursors of Formula IV and Formula V, especially the hydrides of such formulae, also have particular utility as CVD or ALD precursors for deposition of Ta metal films as barriers in integrated circuits.

The present invention in one particular aspect relates to tantalum-containing barrier films, such as may usefully be employed as diffusion barriers in semiconductor devices featuring copper metallization, and reflects the discovery that nitrogen-free Ta alkylidene compounds can be used to efficiently form tantalum-based barrier films at low temperature under reducing conditions.

The Ta alkylidene compounds usefully employed for forming the Ta-containing barrier film may be of any suitable type, including a Ta═C and Ta—C moiety and substituents that permit sufficient carbon to be incorporated in the Ta-containing barrier film to ensure that the barrier film constitutes an amorphous structure.

In one embodiment of the invention, the Ta alkylidene compound used as a precursor for forming an amorphous, nitrogen-free Ta-containing film is a compound of the formula (IV) below: 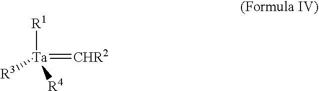
wherein: R¹, R², R³ and R⁴ can be the same as or different from one another, and each is independently selected hydrocarbyl (e.g., C₁-C₈ alkyl, C₂-C₆ alkenyl, etc.), halogen (chlorine, fluorine, bromine, iodine), and silyl.

One particularly preferred Ta alkylidene compound for such purpose is tantalum neopentylidene ((Bu^{t}CH₂)₃Ta(═CHBu^{t})), wherein Bu^{t}=tert-butyl.

The Ta alkylidene compounds are readily synthesized, e.g., by a synthesis route including Grignard reaction of an alkyl chloride starting material with magnesium, reaction with a zinc halide to form a corresponding zinc alkyl compound, reaction with a Ta pentahalide to form a corresponding Ta dihalide compound, and reaction with an alkyllithium compound to form the Ta alkylidene product.

Such synthesis route has been exemplified hereinabove (as Scheme C) for the synthesis of Ta neopentylidene.

In use, the Ta alkylidene precursor can be volatilized to form a precursor vapor for CVD or ALD formation of the Ta-containing barrier film. The precursor volatilization and delivery to the deposition chamber can be carried out in any suitable manner, e.g., by bubbler delivery involving an inert or reducing carrier gas flow through the bubbler, or by solid delivery technique, in which the precursor is volatilized from a solid form under suitable temperature and pressure, e.g., vacuum conditions involving sublimation of the precursor compound and mixing of the precursor vapor with inert or reducing carrier gas, or by liquid delivery technique in which the precursor is dissolved in a suitable solvent medium, such as hexane, octane, or other organic solvent, with the resulting liquid being flash vaporized to produce the precursor vapor, or by any other appropriate technique that results in the provision of a precursor vapor suitable for contacting with the substrate.

The precursor vapor can contain or be mixed with a reducing agent of appropriate character and concentration to provide a suitable reducing atmosphere in the deposition chamber. In the deposition chamber, the substrate on which the barrier film is to be formed, is heated to temperature effective for contacting with the precursor vapor to effect the film formation process, and then contacted with the precursor vapor to form the Ta-containing barrier film on the substrate.

The reducing agent can be hydrogen, hydrogen plasma, remote hydrogen plasma, silane, disilane, borane, diborane, or the like, or mixture of two or more of the foregoing species, as satisfactory to provide an atmosphere in the deposition chamber that facilitates the formation of the Ta-containing film. The reducing co-reactants may be introduced simultaneously with the Ta precursor or in an alternating manner (i.e., via digital or pulsed CVD or ALD). Although the present invention is directed to formation of nitrogen-free Ta-containing films, it will be recognized that when nitrogen poisoning is not an issue in the formation of the barrier layer, other reducing agents such as hydrazines, ammonia, or the like, may be usefully employed in the formation of the barrier film, if they react appropriately with chemisorbed or partially reacted Ta alkylidene without the occurrence of detrimental gas phase reactions that undesirably decrease the deposition rate.

The substrate can be of any appropriate type. In one embodiment, the substrate includes a silicon wafer having a low k dielectric film thereon, suitably patterned for the deposition of the barrier film to accommodate subsequent copper metallization of the semiconductor device structure formed on the wafer.

The deposition is carried out at temperature to form the Ta-containing barrier layer that is appropriate for the specific technique that is employed for the deposition, e.g., CVD, ALD, digital CVD, pulsed CVD, or the like. In general, temperature of 100° C. or higher, but below 400° C., can be utilized as the deposition temperature. In preferred practice, the temperature for deposition is below 390° C., and specific operating regimes for the process include temperature in a range of from 250° C. to 380° C. in one embodiment of the invention, and temperature in a range of from 275° C. to 350° C. in another embodiment of the invention. ALD may for example be carried out at a temperature of 280° C. Pressure may likewise be selected based on volatilization, transport and deposition properties of the specific precursor employed, with vacuum pressures being useful in some applications, e.g., where solid delivery is employed as the delivery technique. CVD and ALD pressures may include deposition pressures in a range of from about 0 to about 1000 Pascal, or other pressure appropriate to the particular deposition methodology.

Ta neopentylidene is a particularly suitable precursor for low temperature deposition applications for formation of Ta-containing films on substrates.

FIG. 3 is a graph of deposition rate, in Angstroms per minute, as a function of temperature (range of 300° C. to 550° C., as well as inverse temperature, 1/T, where T is the temperature in degrees Kelvin), using as the precursor tantalum neopentylidene ((Bu^{t}CH₂)₃Ta(═CHBu^{t})), wherein Bu^{t}=tert-butyl, in a hydrogen atmosphere in the deposition chamber, at pressure of 400 millitorr (“400 mTorr”), 800 millitorr (“800 mTorr”), 2500 millitorr (“2500 mTorr”) and 8000 millitorr (“800 mTorr”), against the comparison case of Ta carbide films formed at higher temperature of 556° C. and at 506° C. (“800 mTorr Nat. Chiao Tung”). The comparison case is described in Yu-Hsu Chang, et al., “Chemical vapor deposition of tantalum carbide and carbonitride thin films from Me₃CE=Ta(CH₂CMe₃)₃ (E=CH,N),” J. Mater. Chem., 2003, 13, 365-369. In contrast to the results of Chang, et al., who achieved deposition rate of only 3 Angstroms per minute at 500° C. in a 50% hydrogen environment, the deposition rates realized in the practice of the present invention were substantially higher at temperature as low as 350° C. in a 4% hydrogen environment in the deposition chamber.

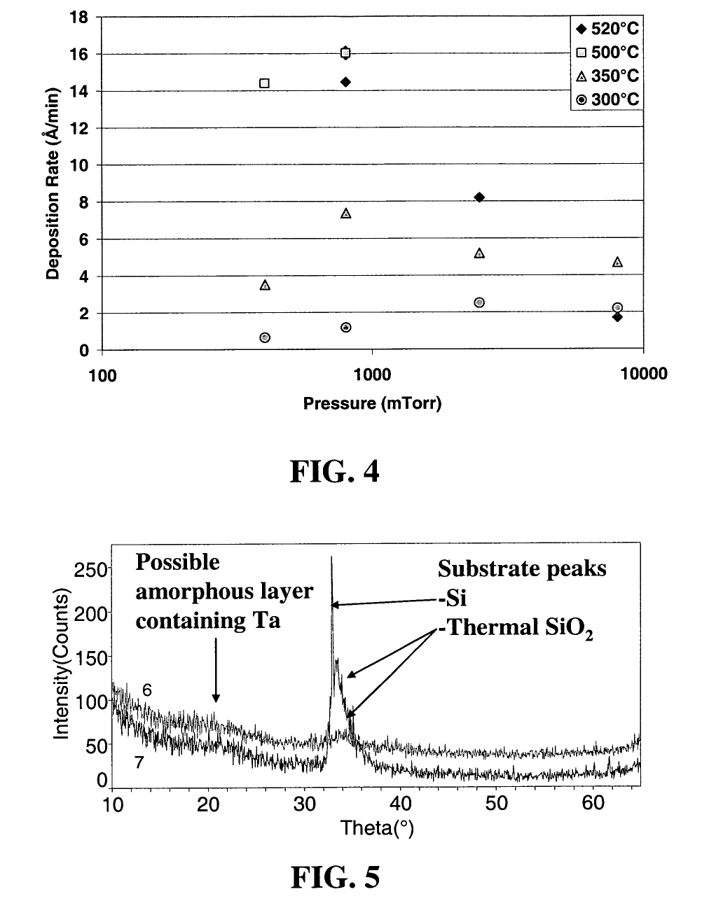

FIG. 4 is a graph of deposition rate, in Angstroms per minute, as a function of pressure, in millitorr, at deposition temperature of 300° C., 350° C., 500° C. and 520° C., using as the precursor tantalum neopentylidene ((Bu^{t}CH₂)₃Ta(═CHBu^{t})), wherein Bu^{t}=tert-butyl, in a hydrogen atmosphere in the deposition chamber. The data show that at high temperature above 500° C., increasing deposition pressure results in steeply declining deposition rate, while at temperature of 300° C. and 350° C., deposition rate increases with increasing pressure.

As a specific example, set out in Table 1 below is a tabulation of process conditions for seventeen runs in which Ta neopentylidene precursor was used to deposit Ta on a substrate. Forming gas was employed as the carrier gas to provide a reducing atmosphere in the deposition chamber. The XRF (Å TaN) parameter in the tabulated data provided a measure of Ta per unit area of film calibrated in units of equivalent TaN thickness. For example, 100 Å TaN indicates that the number of Ta atoms per unit film area is equivalent to that of 100 Å of fully dense TaN.

TABLE 1

| | Substrate | | Forming | Run | | Film | Inverse | Growth |
|---|---|---|---|---|---|---|---|---|
| Run | Temp., | Pressure, | Gas Flow | Time, | XRF | Resistivity, | Temp., | rate, |
| number | ° C. | mTorr | Rate, sccm | sec. | (Å TaN) | μohm-cm | 1/T° K | Å/min. |
| 1 | 520 | 800 | 500 | 600 | 161.35 | 85407 | 0.001262 | 16.135 |
| 2 | 520 | 800 | 500 | 600 | 159.2 | 3402 | 0.001262 | 15.92 |
| 2 | 520 | 800 | 500 | 600 | 144.6 | 0 | 0.001262 | 14.46 |
| 4 | 520 | 2500 | 500 | 600 | 81.9 | 200655 | 0.00126 | 8.19 |
| 5 | 520 | 8000 | 500 | 600 | 17 | 0 | 0.001261 | 1.7 |
| 6 | 500 | 800 | 500 | 600 | 160.3 | 2916 | 0.001293 | 16.03 |
| 7 | 500 | 400 | 500 | 600 | 144 | 1000 | 0.001294 | 14.4 |
| 8 | 450 | 400 | 500 | 600 | 124 | — | 0.001383 | 12.4 |
| 9 | 450 | 800 | 500 | 600 | 129 | — | 0.001383 | 12.9 |
| 10 | 400 | 400 | 500 | 600 | 84 | — | 0.001486 | 8.4 |
| 11 | 400 | 800 | 500 | 600 | 98 | — | 0.001486 | 9.8 |
| 12 | 350 | 400 | 500 | 600 | 35.2 | — | 0.001605 | 3.52 |
| 13 | 350 | 800 | 500 | 600 | 73.7 | — | 0.001605 | 7.37 |
| 14 | 300 | 400 | 500 | 600 | 6.4 | — | 0.001605 | 0.64 |
| 15 | 300 | 800 | 500 | 600 | 11.8 | — | 0.001745 | 1.18 |
| 16 | 350 | 2500 | 500 | 600 | 52 | — | 0.001605 | 5.2 |
| 17 | 350 | 8000 | 500 | 600 | 47 | — | 0.001605 | 4.7 |
| 18 | 300 | 2500 | 500 | 600 | 25 | | 0.001745 | 2.5 |
| 19 | 300 | 8000 | 500 | 600 | 22 | | 0.001745 | 2.2 |

The data in Table 1 show that it is possible to achieve good film growth rates at temperatures below 400° C., e.g., at temperature in a range of 300° C. to 400° C., such as is desirable to minimize adverse effects on the semiconductor device structure to which the barrier layer is being applied, as well as minimizing energy needed for the deposition process, while achieving films of desired amorphous character.

FIG. 5 is an X-ray diffraction spectrum of films of runs 6 and 7 of Table 1, using Cu Kₐₗₚₕₐ radiation monochromated with a crystal monochrometer. There are no diffraction peaks from crystalline phases other than the substrate. The broad peak around 20-22° can be attributed to the amorphous, tantalum-carbon-containing film. The absence of grain boundaries in the amorphous film is advantageous for reducing diffusion of species such as copper through the barrier layer.

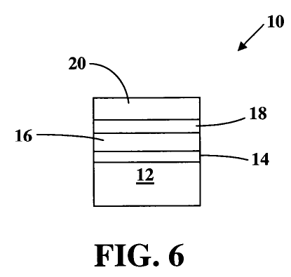

FIG. 6 is a schematic illustration of a semiconductor device structure 10 according to one embodiment of the present invention, featuring an amorphous Ta-containing barrier film and copper metallization.

The device structure 10 includes a silicon substrate 12, on which has been deposited a low k dielectric material 14. An amorphous Ta-containing barrier film 16 is deposited on the dielectric in accordance with the invention, and overlaid with a seed layer 18 of copper, on which is deposited a copper metallization layer 20. The Ta-containing barrier film may be of any suitable thickness, e.g., from about 10 Angstroms to about 1000 Angstroms, or greater, depending on the nature of the dielectric and the overall processing scheme including process temperature in the other fabrication steps of the device manufacturing operation.

In an alternative embodiment, the seed layer may be composed of ruthenium or other suitable seed for deposition of copper metallization.

Thus, a nitrogen-free tantalum alkylidene compound can be used to efficiently and cost-effectively deposit a tantalum-containing film in a reducing atmosphere at low temperature, to produce an amorphous Ta-containing barrier against copper diffusion, in semiconductor device structures featuring copper metallization. The invention thereby achieves a significant advance in the art of copper metallization, avoiding the necessity of using nitrogen-containing precursors to form corresponding barrier layers in the device structure, with the adverse characteristics of such nitrogen-containing precursors.

The R group substituents of tantalum compositions of formulae I-V hereof can further include variations and derivatives of the chemical moieties specifically identified herein, e.g., in respect of hydrocarbyl substituents including alkyl, arylalkyl, alkaryl, alkenyl, alkenylaryl, arylalkenyl, allyl, etc. that are optionally further substituted with heteroatoms such as N, S, and O and/or with halo substituents, providing functionality that is sterically and chemically appropriate to the use of the tantalum composition as a precursor for forming tantalum-containing films and materials. The tantalum compositions of the invention can be utilized in solution including any suitable solvents, such as for example hydrocarbon solvents (hexane, pentane, etc.), THF, ethers (e.g., DME), and the like, as necessary or desirable in a given application of a specific tantalum composition of the invention.

Although the invention has been described herein with reference to illustrative features, aspects and embodiments, it will be appreciated that the invention may be practiced with modifications, variations and in other embodiments, as will suggest themselves to those of ordinary skill based on the disclosure herein. The invention therefore is to be interpreted and construed, as encompassing all such modifications, variations, and other embodiments, within the spirit and scope of the claims hereafter set forth.

What is claimed is:

1. A tantalum composition, selected from the group consisting of compositions of Formulae I-V below: 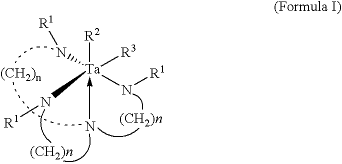
wherein: R₁, R₂, and R₃ can be the same as or different from one another, and each is independently selected from hydrocarbyl, hydrogen, halogen, silyl, hydrazide and amino; and n is an integer having a value of from 1 to 4 inclusive; 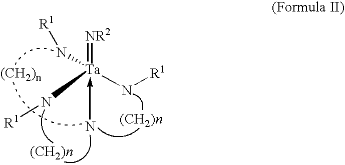
wherein: R₁ and R₂ can be the same as or different from one another, and each is independently selected from hydrocarbyl, hydrogen, halogen, silyl, hydrazide and amino; and n is an integer having a value of from 1 to 4 inclusive; 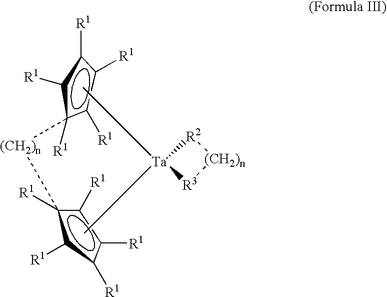
wherein: R¹, R² and R³ can be the same as or different from one another, and each is independently selected from hydrogen and hydrocarbyl(ene) substituents; and n is selected from the values of 0, 1, 2, 3 and 4, with the proviso that when n is not zero, R² and R³ can be the same as or different from one another, and each is independently selected from bidentate hydrocarbyl ligands; 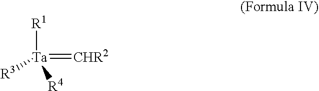
wherein: R¹, R², R³ and R⁴ can be the same as or different from one another, and each is independently selected from hydrogen and hydrocarbyl, halogen, silyl, hydrazide and amino; and 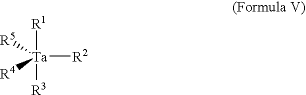
wherein: R¹, R², R³ and R⁴ and R⁵ can be the same as or different from one another, and each is independently selected from hydrogen and hydrocarbyl, halogen, silyl, hydrazide and amino.

2. A tantalum precursor formulation, comprising a tantalum composition as claimed in claim 1, in a solvent medium.

3. A method of synthesizing a tantalum composition as claimed in claim 1, comprising conducting synthesis according to a procedure selected from the group of synthesis procedures consisting of Scheme A, Scheme B and Scheme C.

4. A method of forming a tantalum-containing material on a substrate, comprising volatilizing a tantalum composition as claimed in claim 1, to form a precursor vapor, and depositing tantalum on the substrate from the precursor vapor under deposition conditions therefor.

5. The method of claim 4, wherein said depositing comprises a deposition technique selected from the group consisting of CVD and ALD.

6. The method of claim 4, comprising a delivery technique selected from the group consisting of liquid delivery and solid delivery.

7. A semiconductor device structure, including a dielectric layer, a barrier layer overlying the dielectric layer, and copper metallization overlying the barrier layer, wherein the barrier layer includes a Ta-containing layer including sufficient carbon so that the Ta-containing layer is amorphous.

8. The device structure of claim 7, wherein the dielectric layer comprises a low k dielectric material.

9. The device structure of claim 7, wherein the Ta-containing layer has a thickness in a range of from about 10 Angstroms to about 1000 Angstroms.

10. The device structure of claim 7, wherein the copper metallization includes a copper seed layer and a bulk copper metallization layer.

11. The device structure of claim 7, wherein the Ta-containing layer is devoid of nitrogen therein.

12. A method of forming a Ta-containing barrier layer on a substrate including a dielectric layer thereon, including depositing the Ta-containing barrier layer by a process including CVD or ALD, from a precursor including a Ta alkylidene compound, at a temperature below 400° C., in a reducing or inert atmosphere.

13. The method of claim 12, wherein said depositing includes CVD.

14. The method of claim 13, wherein said depositing includes digital CVD.

15. The method of claim 13, wherein said depositing includes pulsed CVD.

16. The method of claim 12, wherein said depositing includes ALD.

17. The method of claim 12, wherein said depositing includes liquid delivery.

18. The method of claim 12, wherein said depositing includes solid delivery.

19. The method of claim 12, wherein said reducing atmosphere includes hydrogen.

20. The method of claim 12, wherein said reducing atmosphere includes forming gas.

21. The method of claim 12, wherein said reducing atmosphere includes a reducing agent selected from the group consisting of hydrogen, silane, disilane, borane, diborane, and compatible mixtures thereof.

22. The method of claim 12, wherein said depositing is carried out at temperature in a range of from 250° C. to 390° C.

23. The method of claim 12, wherein said depositing is carried out at temperature in a range of from 250° C. to 380° C.

24. The method of claim 12, wherein said depositing is carried out at temperature in a range of from 275° C. to 350° C.

25. The method of claim 12, wherein the Ta alkylidene compound is of the formula: 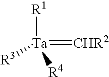
wherein: R¹, R², R³ and R⁴ can be the same as or different from one another, and each is independently selected from hydrocarbyl, halogen, and silyl.

26. The method of claim 25, wherein said hydrocarbyl is selected from the group consisting of C₁-C₈ alkyl and C₂-C₆ alkenyl.

27. The method of claim 25, wherein each of R¹, R³ and R⁴ is neopentyl, and R² is t-butyl.

28. The method of claim 12, wherein the Ta alkylidene compound includes tantalum neopentylidene.

29. A method of inhibiting copper migration in a structure including copper and material adversely affected by copper migration, comprising providing a Ta-containing barrier layer between said copper and said material, including depositing the Ta-containing barrier layer by a process including CVD or ALD, from a precursor including a Ta alkylidene compound, at a temperature below 400° C., in a reducing or inert atmosphere.

30. A method of making a semiconductor device, comprising forming a migration barrier by a vapor deposition process using a vapor deposition precursor including a tantalum composition according to claim 1.

31. A method of semiconductor manufacturing, comprising use of a tantalum composition according to claim 1.
